(19) United States
(12) Patent Application Publication
(10) Pub. No.: US 2024/0359329 A1
(43) Pub. Date: Oct. 31, 2024

(54) PICKING AN ELECTRONIC COMPONENT FROM A REUSABLE ADHESIVE TAPE

(71) Applicant: ASMPT Singapore Pte. Ltd., Singapore (SG)

(72) Inventors: Wai Lam NG, Hong Kong (CN); Chi Piu WONG, Hong Kong (CN); Hon Keung LEE, Hong Kong (CN); Yuen Wai LEE, Hong Kong (CN); Yin Fun NG, Hong Kong (CN)

(21) Appl. No.: 18/139,611

(22) Filed: Apr. 26, 2023

(51) Int. Cl. B25J 9/16; B25J 11/00; B25J 15/00; B25J 15/06

(52) U.S. Cl. CPC B25J 9/1679; B25J 11/005; B25J 15/0028; B25J 15/0033; B25J 15/0616

(57) ABSTRACT

A method of picking an electronic component from an adhesive tape on which the electronic component is mounted which includes selecting a electronic component from a plurality of electronic components arranged on the adhesive tape, each electronic component being located on the adhesive tape over an associated support upstanding from a support bed; displacing the adhesive tape towards the support bed to peel the adhesive tape from edges of the electronic component; and displacing a gripper to detach the electronic component from the adhesive tape.

### FIELD OF THE INVENTION

The invention relates to a method of picking an electronic component, such as an image sensor, from an adhesive tape that is reusable after the said pick-up, and an apparatus for picking such an electronic component from a reusable adhesive tape.

### BACKGROUND

The manufacture of electronic products requires high quality and reliability during the manufacturing process. In particular, process accuracy and consistency are important for semiconductor assembly and packaging equipment. One manufacturing process involves picking and detaching an image sensor from an adhesive tape which typically secures a plurality of image sensors affixed to that adhesive. Such an image sensor can be incorporated into an image sensor module and be attached to a lens holder or other component or assembly.

The sensor will typically go through multiple processes during assembly, including die bonding, wire bonding, oven cure, and the like. During these processes, the sensors are placed on an adhesive (sticky) tape carried by a carrier, typically in a matrix arrangement. The equipment of each assembly step will receive the carrier and work on the sensors carrier by carrier. However, in some processes (such as automatically conducting active alignment (AA)), each sensor may need to be separated or detached from the tape carrier, so that the equipment can process each sensor individually—this is often referred to as a de-tape process.

In one example of a de-tape apparatus, such as that described in China patent publication number CN106624749B entitled “Full-automatic stripping machine for mobile phone camera module”, the apparatus may have a gripper that clamps one end of the tape and peels it off the carrier. As the tape is being peeled off, the sensors are loosened from the tape and slide off the tape onto a platform. These sensors can then be picked up and placed on typically a metal carrier, which is then provided to, for example, the AA equipment. The de-tape apparatus can also be implemented as a manual jig. A factory worker will manually pick up the sensors by hand using tools, such as a tweezer, but such manual pick-up significantly reduces productivity.

After the metal carrier is provided to the AA equipment, the sensor will be picked up and transferred to a Sensor Unit Transport (SUT), where the sensor will be powered on to activate its image capture function. A corresponding lens holder will be picked up and placed above the image sensor to perform AA. After the said AA, the lens holder and image sensor will be coupled together and assembled into a completed camera module. This camera module will be picked up and transferred back to the metal carrier.

Once all the sensors on the carrier are processed, the carrier will be transferred out of the AA equipment. In some arrangements, the de-tape function can be integrated into the AA equipment, where the sensor will be picked up from the platform and placed directly onto the AA station, by-passing the metal carrier process. However, some problems may be encountered when de-taping the sensor from the tape. For instance, the tape carriers are effectively destroyed since the tape is damaged as the sensors are detached and fresh tape carriers are needed to receive the processed sensors. In particular, the tape carriers often cannot be reused and a new tape carrier needs to be provided and swapped for the previous tape carrier in the de-tape apparatus for the processed sensors that have been processed in the aforesaid manner in which the adhesive tape can no longer be reused.

It would be beneficial to provide an improved method for picking a sensor from an adhesive tape as compared to the prior art.

### SUMMARY OF THE INVENTION

It is thus an object of this invention to seek to provide a method and apparatus which overcomes at least some of the aforementioned problems of the prior art.

According to a first aspect of the present invention, there is provided a method of picking an electronic component from an adhesive tape on which the electronic component is mounted, the method comprising: selecting an electronic component from a plurality of electronic components arranged on the adhesive tape, each electronic component being located on the adhesive tape over an associated support upstanding from a support bed; displacing the adhesive tape towards the support bed to peel the adhesive tape from edges of the electronic component; and displacing a gripper to detach the electronic component from the adhesive tape.

The first aspect recognizes that a problem with some existing arrangements is that it can be difficult or complicated to remove an electronic component from the adhesive tape and that the removal can typically result in the adhesive tape being damaged and therefore cannot be reused. Accordingly, a method is provided. The method may be for picking or detaching an electronic component or other device from an adhesive tape on which the electronic component may be mounted or attached. The method may comprise selecting an electronic component arranged or positioned on the adhesive tape. The electronic component may be selected from a plurality of electronic components. The or each electronic component may be located or positioned on the adhesive tape over, above or co-located with an associated support upstanding, extending or protruding from a support bed. The method may comprise displacing, moving or flexing the adhesive tape towards the support bed or away from the electronic component to peel or detach the adhesive tape at least from an edge of the electronic component. The method may comprise displacing a gripper to detach, peel or remove the electronic component from the adhesive tape. In this way, an effective and reliable technique for removing the electronic component from the adhesive tape is provided which avoids damage to the adhesive tape, to enable the adhesive tape to subsequently be reused. This helps to reduce manpower requirements and helps to utilize cleanroom space as well as reducing waste, make production more cost-effective and environmentally-friendly.

The method may comprise positioning the electronic component such that the support is centrally located below the electronic component. This helps to ensure that the electronic component is adequately supported by the support as the adhesive tape is displaced for peeling.

The support may be unitary and does not or fails to extend to the edges of the electronic component. This helps to ensure that the electronic component at least partially overhangs the support, thereby enabling the adhesive tape to be peeled at least from an edge of the electronic component during the displacement of the adhesive tape.

The support may extend longitudinally along a length of the electronic component and the support may have a support surface that is smaller than a surface area of the electronic component facing the support surface. Again, this helps to support the electronic component during displacement of the adhesive tape whilst allowing the adhesive tape to be peeled at least from an edge of the electronic component.

The support may be immovably arranged on the support bed. In other words, the support may be a static structure. This reduces the complexity of the support and the support bed.

The displacing may comprise displacing the adhesive tape into a void, volume or chamber defined between the adhesive tape and the support bed. Hence, the adhesive tape may be displaced into a space below the electronic component and above the support bed to allow the adhesive tape to be peeled at least from an edge of the electronic component.

The displacing may comprise displacing the adhesive tape into the void using a vacuum applied to the void. In other words, the tape may be sucked into the space beneath the electronic component and above the support bed to peel the adhesive tape from at least an edge of the electronic component.

The displacing may comprise displacing, moving or pushing the adhesive tape to peel the adhesive tape from at least an edge of the electronic component using the gripper. Accordingly, the gripper itself may be used to displace the adhesive tape in order to peel it from at least an edge of the electronic component instead of, or in addition to, using a vacuum.

The displacing may comprise displacing the adhesive tape by inserting at least a portion or part of the gripper between the electronic component and the adhesive tape.

The gripper may comprise a pair of jaws and the method may comprise gripping the electronic component between the pair of jaws.

Each jaw may define a gripping recess and the gripping may comprise gripping the electronic component within the gripping recesses of the pair of jaws. Providing recesses helps to reliably hold the electronic component in a predetermined position.

At least one gripping recess may have a sloping edge and the gripping may comprise aligning the electronic component with the gripping recess using the sloping edge. Accordingly, any misalignment between the gripper jaws and the electronic component may be accommodated by the provision of the sloping edge to help reliably align and grip the electronic component with the gripper.

The gripper may comprise a vacuum collet and the method may comprise holding the electronic component with a vacuum suction force generated from the vacuum collet. Accordingly, rather than gripping the electronic component between a pair of gripper jaws, which may be problematic for some configurations of electronic components which may be susceptible to mechanical damage, a vacuum collet may instead be used to hold the electronic component in place with a suction force.

The vacuum collet may define a holding recess shaped to receive the electronic component and the gripping may comprise holding the electronic component within the holding recess using the vacuum collet. The provision of the holding recess may help to accurately position the electronic component on the vacuum collet and resist any rotational slippage of the electronic component on the vacuum collet.

The method may comprise, after the displacing, detaching the electronic component from the adhesive tape using the gripper, leaving the adhesive tape intact for subsequent reuse. Accordingly, the electronic component may be removed from the adhesive tape without leading to damage of the adhesive tape, thereby enabling the adhesive tape to be reused.

The adhesive tape may be retained on a planar, rigid carrier extending around a perimeter of the adhesive tape and the displacing of the gripper may detach the electronic component from the adhesive tape, leaving the adhesive tape intact on the carrier.

The carrier may be configured to be coupled over the support bed for positioning the adhesive tape and the electronic component over the support.

The displacing of the gripper may comprise rotating the gripper while displacing it to detach the electronic component from the adhesive tape. The rotation may assist in detaching any remaining adhered portion of the electronic component from the adhesive tape before lifting the gripper away from the adhesive tape to detach the electronic component from the adhesive tape.

The adhesive tape may comprise a plurality of electronic components attached to the adhesive tape, each located over a respective one of a plurality of supports upstanding from the support bed.

The method may comprise reusing the adhesive tape by placing an electronic component previously detached from the adhesive tape back on to the adhesive tape.

According to a second aspect of the present invention, there is provided an apparatus for picking an electronic component from an adhesive tape on which the electronic component is mounted, comprising: a support bed and a plurality of supports upstanding from the support bed, each support being located at a position for receiving an associated electronic component mounted on the adhesive tape laid on a carrier when the adhesive tape is placed over the support bed; a controller configured to select an electronic component from the plurality of electronic components arranged on the adhesive tape and to control displacing the adhesive tape towards the support bed to peel the adhesive tape from edges of the electronic component; and a gripper configured to be displaced to detach the electronic component from the adhesive tape.

The electronic component may be positioned such that the support is the support centrally located below the electronic component.

The support may be unitary and may be dimensioned not extend to edges of the electronic component.

The support may extend longitudinally along a length of the electronic component and the support may have a support surface that is smaller than a surface area of the electronic component facing the support surface.

The support may be immovably arranged on the support bed.

The controller may be configured to control displacing the adhesive tape into a void defined between the adhesive tape and the support bed.

The controller may be configured to control displacing of the adhesive tape into the void using a vacuum applied to the void.

The controller may be configured to control displacing the adhesive tape using the gripper.

The controller may be configured to control displacing the adhesive tape by inserting at least a portion of the gripper between the electronic component and the adhesive tape.

The gripper may comprise a pair of jaws and the controller may be configured to control the gripper to grip the electronic component between the pair of jaws.

Each jaw may define a gripping recess and the controller may be configured to control the gripper to grip the electronic component within the gripping recesses of the pair of jaws.

At least one gripping recess may have a sloping edge and the controller may be configured to control the gripper to align the electronic component within the gripping recess using the sloping edge.

The gripper may comprise a vacuum collet and the controller may be configured to control the gripper to hold the electronic component with a vacuum suction force generated from the vacuum collet.

The vacuum collet may define a holding recess shaped to receive the electronic component and the gripping may comprise holding the electronic component within the holding recess using the vacuum collet.

The controller may be configured to control the gripper, after the displacing, to detach the electronic component from the adhesive tape leaving the adhesive tape intact for subsequent reuse.

The adhesive tape may be retained on a planar, rigid carrier extending around a perimeter of the adhesive tape and the controller may be configured to control the gripper to detach the electronic component from the adhesive tape leaving the adhesive tape intact on the carrier.

The carrier may be configured to be coupled over the support bed for positioning the adhesive tape and electronic component over the support.

The controller may be configured to rotate the gripper while displacing it to detach the electronic component from the adhesive tape before lifting the gripper away from the adhesive tape to detach the electronic component from the adhesive tape.

The adhesive tape may comprise a plurality of electronic components attached to the adhesive tape, each located over a respective one of a plurality of supports upstanding from the support bed.

The controller may be configured to control the gripper to reuse the adhesive tape by placing an electronic component previously detached from on the adhesive tape back onto the adhesive tape.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1 illustrates an exemplary image sensor according to one embodiment;

FIG. 2 illustrates an exemplary adhesive tape assembly and a support bed of an exemplary de-tape apparatus according to one embodiment;

FIG. 3 illustrates main parts of the exemplary de-tape apparatus according to one embodiment;

FIG. 4A is an isometric view of the gripper jaws when gripping a sensor;

FIG. 4B is an isometric view of a cross-section through the gripper jaws;

FIG. 4C is a plan sectional view through the gripper jaws;

FIG. 4D is an end view of the gripper jaws;

FIG. 4E shows a view of the rotary gripper;

FIG. 5 illustrates a first technique for picking the sensor from the adhesive tape according to one embodiment;

FIG. 6 illustrates another technique for picking the sensor from the adhesive tape according to one embodiment; and

FIG. 7 illustrates another technique for picking the sensor from the adhesive tape according to one embodiment.

In the drawings, like parts are denoted by like reference numerals.

### DETAILED DESCRIPTION

Before discussing the embodiments in any more detail, first an overview will be provided. Some embodiments provide an arrangement for removing an electronic component, such as an image sensor, from an adhesive or sticky tape or substrate on which the electronic component or sensor is mounted. A support bed is typically provided having one or more supports which extend towards an overlying adhesive tape. A sensor is typically positioned on the adhesive tape over an associated support. The adhesive tape is typically displaced to peel the adhesive tape away from at least an edge of the sensor, which remains supported by the underlying support. A gripper is typically used to detach the sensor from the adhesive tape and lift it away from the adhesive tape for processing.

The tape is typically displaced from at least an edge of the sensor by applying a vacuum to a plenum defined between the adhesive tape and the support bed and/or by a portion of the gripper itself being positioned between the sensor and the adhesive tape. The removal of the sensor from the adhesive tape may be facilitated by rotating the sensor to assist in detaching it from the adhesive tape. This arrangement enables the sensor to be reliably removed from the adhesive tape while avoiding damage to the adhesive tape, enabling the adhesive tape to be reused which helps to reduce waste and the requirement for human intervention.

### Sensor

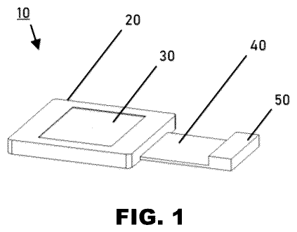

FIG. 1 illustrates an exemplary image sensor 10 according to one embodiment. The sensor 10 comprises a main body 20, a glass window 30, a flexible printed circuit 40 and a connector 50. However, it will be appreciated that other sensors or module configurations may be used.

### Tape Assembly

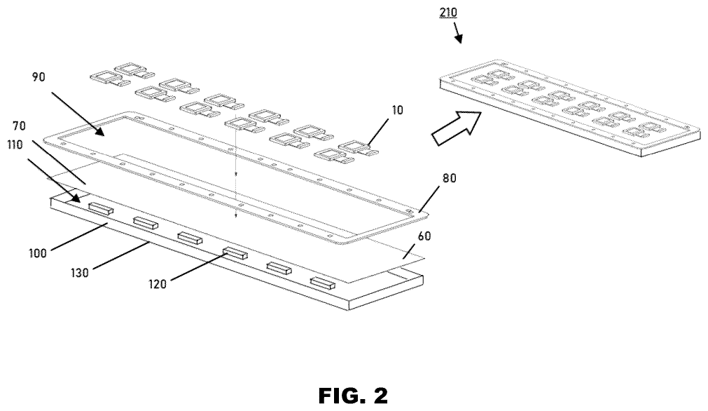

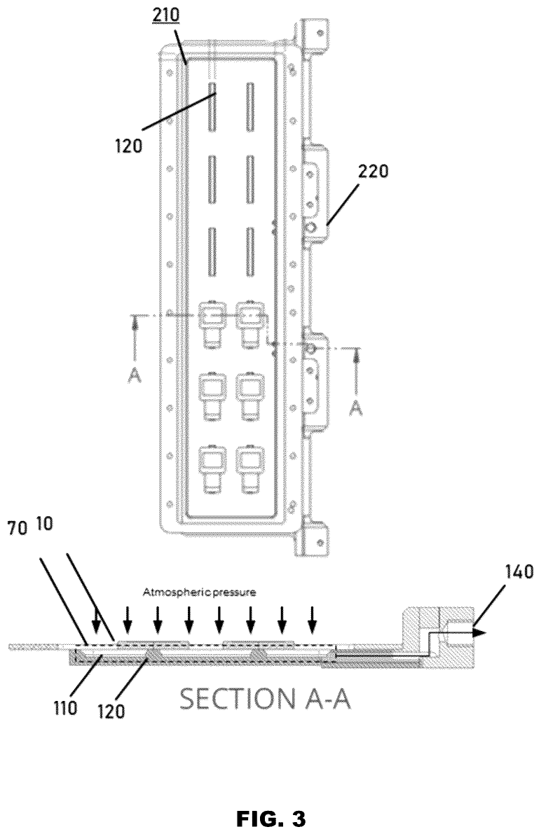

FIG. 2 illustrates an exemplary adhesive tape assembly 210 and a support bed 100 of an exemplary de-tape apparatus 220 (see FIG. 3) according to one embodiment. An adhesive tape 60 is provided with an adhesive side 70. The adhesive tape 60 is typically flexible, deformable and often stretchable. In this arrangement, the adhesive tape 60 is generally rectangular in shape, but it will be appreciated that other shapes are possible. The adhesive tape 60 is received by and typically adheres to a carrier 80 with an adhesive side 70 of the adhesive tape 60. The carrier 80 provides a rigid perimeter frame which holds the adhesive tape 60 in a generally planar configuration, extending across an aperture 90 defined by the carrier 80. Sensors 10 are positioned in rows and columns on the adhesive side 70 of the adhesive tape 60.

Separately, the support bed 100 is in the form of a recessed tray. The support bed 100 defines a cavity 110 below the adhesive tape 60 that is placed over the support bed 100. A plurality of supports 120 upstand or protrude from a base 130 of the support bed 100 towards the adhesive tape 60. The supports 120 are dimensioned and positioned to be located beneath the sensors 10 which are placed on the adhesive tape 60. For example, in this arrangement where the sensors 10 are positioned in rows and columns on the adhesive tape 60, the supports 120 are also positioned in corresponding rows and columns at predetermined locations where the sensors 10 are to be placed. Typically, the supports 120 have a length or major dimension, and are positioned to extend along a corresponding length or major dimension of the sensor 10 and orientated along that major dimension. Typically, the support 120 further has a width or minor dimension which is dimensioned to be no wider than a corresponding width or minor dimension of the sensor 10. Hence, it can be seen that each support 120 is arranged in an island arrangement. In this arrangement, each support 120 has the same height, is approximately 3 mm wide and has sloped sides, but other configurations are possible.

### De-Tape Apparatus

FIG. 3 illustrates main parts of the exemplary de-tape apparatus 220 according to one embodiment. The adhesive tape assembly 210 has been received by the de-tape apparatus 220. Vacuum conduits 140 are provided in the de-tape apparatus 220 which are in fluid communication with a vacuum pump (not shown) and with the cavity 110.

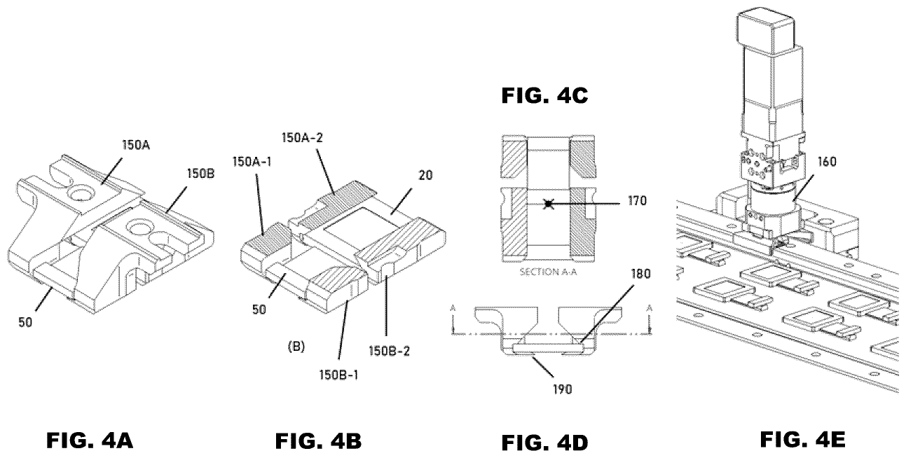

FIGS. 4A to 4E illustrate gripper jaws 150A, 150B of a rotary gripper 160 of the de-tape apparatus 220 according to one embodiment. FIG. 4A is an isometric view of the gripper jaws 150A, 150B when gripping a sensor 10. FIG. 4B is an isometric view of a cross-section through the gripper jaws 150A, 150B for which each gripper jaw has two parts 150A-1, 150A-2, 150B-1, 150B-2 for gripping the connector 50 and the main body 20 of the sensor 10, respectively. FIG. 4C is a plan sectional view through the gripper jaws 150A, 150B showing the centre of rotation 170 of the rotary gripper 160. In this example, the centre of rotation 170 is located close to the connection point between the main body and the flexible printed circuit 40 to reduce stresses on these components. As can be seen in FIG. 4D, which is an end view of the gripper jaws 150A, 150B, each gripper jaw defines a recess 180 which is dimensioned to receive a corresponding part of the sensor 10. The recesses 180 are typically dimensioned to match the edge profile of the sensor 10. The recess may define at least one sloping edge 190 which helps to locate the sensor within the recess 180.

### Exemplary Operation

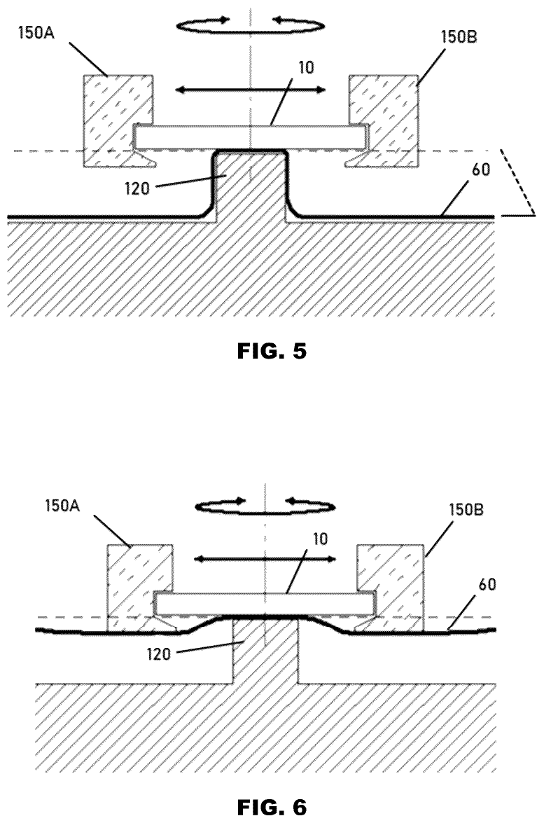

FIG. 5 illustrates a first technique for picking the sensor 10 from the adhesive tape 60. In this arrangement, the required sensor 10 is identified and selected by a controller (not shown). The controller controls the application of a vacuum via the vacuum conduits 140 to reduce the air pressure within the cavity 110, which deforms the adhesive tape 60 and partially peels the adhesive tape 60 to partially detach the sensor 10 from the adhesive tape 60 when the sensor 10 is resting on the support 120. The controller controls the rotary gripper 160 to grip the sensor 10 using the gripper jaws 150A, 150B. At this point, the rotary gripper 160 rotates the sensor 10 which detaches the sensor 10 completely from the adhesive tape 60. This removes the sensor 10 from the adhesive tape 60 while avoiding damage to the adhesive tape 60, enabling the adhesive tape 60 to be reused. For example, the position vacated by the sensor 10 can then be filled by another sensor 10, or the removed sensor 10 can be placed back in that position once any off-tape processing has completed. Once the sensor 10 has been removed, the vacuum can be removed and the adhesive tape 60 returns to a generally-planar configuration.

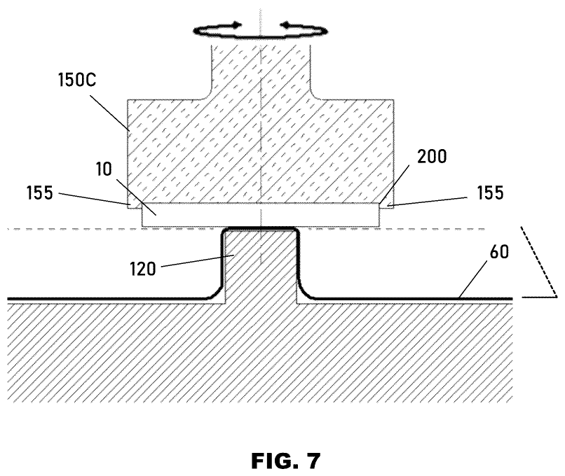

FIG. 6 illustrates another technique for picking the sensor 10 from the adhesive tape 60. The required sensor 10 is identified and selected by the controller. In this arrangement, no vacuum needs be applied and instead the controller controls the gripper jaws 150A, 150B which themselves displace the adhesive tape 60, thereby partially detaching the sensor 10 from the adhesive tape 60 as the gripper jaws 150A, 150B close to grip the sensor 10. In particular, the portion of the gripper jaws 150A, 150B which define the sloping edge 190 are interposed or inserted between the sensor 10 and the adhesive tape 60 and partially peels the adhesive tape 60 to partially detach the sensor 10 from the adhesive tape 60. The rotary gripper 160 grips the sensor 10 using the gripper jaws 150A, 150B. At this point, the rotary gripper 160 rotates the sensor 10 which detaches the sensor completely from the adhesive tape 60. This removes the sensor 10 from the adhesive tape 60 while avoiding damage to the adhesive tape 60, enabling the adhesive tape 60 to be reused. For example, the position vacated by the sensor 10 can then be filled by another sensor 10, or a removed sensor 10 can be placed back in that position once the relevant off-tape processing has been completed. Once the sensor 10 has been removed the adhesive tape 60 resiliently returns to a generally-planar configuration.

FIG. 7 illustrates another technique for picking the sensor 10 from the adhesive tape 60. The required sensor 10 is identified and selected by the controller. In this arrangement, a different configuration of rotary gripper 160 is provided. In this arrangement, rather than having gripper jaws 150A, 150B, a vacuum collet 150C is provided instead. The facing profile of the vacuum collet 150C is typically dimensioned to match the facing profile of the sensor 10. The vacuum collet 150C is typically recessed to define a holding recess bounded by an abutment 155 on at least one end of the collet 150C which is aligned with one side of the sensor 10. This helps to retain the sensor 10 in an accurate position on the vacuum collet 150C. Further, the abutment 155 helps to actuate rotation of the sensor during rotation of the rotary gripper 160 to detach the sensor 10 completely from the adhesive tape 60. The controller controls the application of a vacuum via the vacuum conduits 140 to reduce the air pressure within the cavity 110, which deforms the adhesive tape 60 and partially peels the adhesive tape 60 to partially detach the sensor 10 from the adhesive tape 60. The controller controls the rotary gripper 160 to grip the sensor 10 using the vacuum collet 150C. The rotary gripper 160 rotates the sensor 10 which detaches the sensor 10 completely from the adhesive tape 60. This removes the sensor from the adhesive tape 60 while avoiding damage to the adhesive tape 60, enabling the adhesive tape 60 to be reused. For example, the position vacated by the sensor 10 can then be filled by another sensor 10, or a removed sensor 10 can be placed back in that position once the relevant off-tape processing has been completed. Once the sensor has been removed, the vacuum can be removed and the adhesive tape 60 resiliently returns to a generally-planar configuration.

Although the present invention has been described in considerable detail with reference to certain embodiments, other embodiments are possible.

Therefore, the spirit and scope of the appended claims should not be limited to the description of the embodiments contained herein.

1. A method of picking an electronic component from an adhesive tape on which the electronic component is mounted, the method comprising:
selecting an electronic component from a plurality of electronic components arranged on the adhesive tape, each electronic component being located on the adhesive tape over an associated support upstanding from a support bed;
displacing the adhesive tape towards the support bed to peel the adhesive tape from edges of the electronic component; and
displacing a gripper to detach the electronic component from the adhesive tape.

2. The method of claim 1, further comprising positioning the electronic component such that the support is centrally located below the electronic component.

3. The method of claim 1, wherein the support is unitary and does not extend to edges of the electronic component.

4. The method of claim 1, wherein the support extends longitudinally along a length of the electronic component and the support has a support surface that is smaller than a surface area of the electronic component facing the support surface.

5. The method of claim 1, wherein the support is immovably arranged on the support bed.

6. The method of claim 1, wherein the displacing comprises displacing the adhesive tape into a void defined between the adhesive tape and the support bed.

7. The method of claim 6, wherein the displacing comprises displacing the adhesive tape into the void using a vacuum applied to the void.

8. The method of claim 6, wherein the displacing comprises displacing the adhesive tape using the gripper.

9. The method of claim 8, wherein the displacing comprises displacing the adhesive tape by inserting at least a portion of the gripper between the electronic component and the adhesive tape.

10. The method of claim 1, wherein the gripper comprises a pair of jaws and the method comprises gripping the electronic component between the pair of jaws to detach the electronic component.

11. The method of claim 10, wherein each jaw defines a gripping recess and the gripping comprises gripping the electronic component within the gripping recesses of the pair of jaws.

12. The method of claim 11, wherein at least one gripping recess has a sloping edge and the gripping comprises aligning the electronic component within the gripping recess using the sloping edge.

13. The method of claim 1, wherein the gripper comprises a vacuum collet and the method comprises holding the electronic component with a vacuum suction force generated from the vacuum collet to detach the electronic component.

14. The method of claim 13, wherein the vacuum collet defines a holding recess bounded on at least one side of the sensor by an abutment shaped to receive the electronic component and the gripping comprises holding the electronic component within the holding recess using the vacuum collet.

15. The method of claim 1, wherein the adhesive tape is retained on a planar, rigid carrier extending around a perimeter of the adhesive tape and the displacing the gripper detaches the electronic component from the adhesive tape leaving the adhesive tape intact on the carrier.

16. The method of claim 15, wherein the carrier is configured to be coupled over the support bed for positioning the adhesive tape and electronic component over the support.

17. The method of claim 1, wherein the displacing the gripper further comprises rotating the gripper while displacing the electronic component to detach the electronic component from the adhesive tape before lifting the gripper away from the adhesive tape to detach the sensor.

18. The method of claim 1, wherein the adhesive tape comprises a plurality of electronic components attached to the adhesive tape, each located over a respective one of a plurality of supports upstanding from the support bed.

19. The method of claim 1, comprising reusing the adhesive tape by placing a electronic component previously detached from the adhesive tape back onto the adhesive tape.

20. An apparatus for picking an electronic component from an adhesive tape on which the electronic component is mounted, comprising:
a support bed and a plurality of supports upstanding from the support bed, each support being located at a position for receiving an associated electronic component mounted on the adhesive tape laid on a carrier when the adhesive tape is placed over the support bed;
a controller configured to select an electronic component from the plurality of electronic components arranged on the adhesive tape and to control displacing the adhesive tape towards the support bed to peel the adhesive tape from edges of the electronic component; and
a gripper configured to be displaced to detach the electronic component from the adhesive tape.
